(19) United States
(12) Patent Application Publication
(10) Pub. No.: US 2022/0330429 A1
(43) Pub. Date: Oct. 13, 2022

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Taichi ITOH, Matsumoto-city (JP)

(73) Assignee: FUJI ELECTRIC CO., LTD., Kawasaki-shi (JP)

(21) Appl. No.: 17/855,162

(22) Filed: Jun. 30, 2022

Related U.S. Application Data
(63) Continuation of application No. PCT/JP2021/020530, filed on May 28, 2021.

(30) Foreign Application Priority Data
Jul. 9, 2020 (JP) 2020-118648

(51) Int. Cl. H05K 1/11; H05K 1/02; H05K 3/32

(52) U.S. Cl. CPC H05K 1/111; H05K 1/0209; H05K 3/32; H05K 2201/10378; H05K 2201/10856; H05K 2201/10757

(57) ABSTRACT

A semiconductor device includes a semiconductor chip, an insulated circuit substrate including an insulating board and a circuit pattern on the insulating board electrically connected to the semiconductor chip, and a wiring member having a leg portion bonded to the circuit pattern. The leg portion includes a vertical portion, a first divided portion, and a second divided portion. The vertical portion extends in a vertical direction orthogonal to a plane of the circuit pattern, and has a split end provided at a side of the vertical portion at which the circuit pattern is disposed. The first divided portion extends from the split end in a first direction parallel to the plane of the circuit pattern and is bonded to the circuit pattern. The second divided portion extends from the split end in a second direction opposite the first direction and is bonded to the circuit pattern.

### CROSS-REFERENCE TO RELATED APPLICATION

This application is a continuation application of International Application PCT/JP2021/020530 filed on May 28, 2021 which designated the U.S., which claims priority to Japanese Patent Application No. 2020-118648, filed on Jul. 9, 2020, the entire contents of which are incorporated herein by reference.

### BACKGROUND OF THE INVENTION

### 1. Field of the Invention

The embodiments discussed herein relate to a semiconductor device and a method of manufacturing the same.

### 2. Background of the Related Art

Semiconductor devices include semiconductor elements such as insulated gate bipolar transistors (IGBTs) and power metal oxide semiconductor field effect transistors (MOSFETs), for example. A semiconductor device includes a heat dissipation plate, and ceramic circuit substrates that are bonded to the heat dissipation plate and that have semiconductor elements disposed thereon. In addition, in the semiconductor device, circuit patterns of the ceramic circuit substrates are electrically connected with lead frames. The lead frames each have a body portion, a plurality of external connection terminals connected to the body portion, and a plurality of leg portions connected to the body portion. The body portion extends and passes over the plurality of ceramic circuit substrates. The external connection terminals are electrically connected to external devices or the like. The external connection terminals input current to the body portion and output current conducting through the body portion to the outside. The leg portions are L-shaped in side view. The leg portions of this type are connected to the body portion along the body portion passing over the plurality of ceramic circuit substrates. The leg portions are electrically bonded to circuit patterns of the individual ceramic circuit substrates to electrically connect each ceramic circuit substrate and the body portion. In this case, the leg portions are bonded to the circuit patterns of the ceramic circuit substrates by ultrasonic bonding. For example, the lead frames are made of copper or a copper alloy.

International Publication Pamphlet No. WO2019/230292

The leg portions of a lead frame are bonded to circuit patterns by ultrasonic bonding. In the bonding, the leg portions may be bonded deviated from planned bonding positions in the vibrating direction. In the case where the plurality of leg portions are bonded by the ultrasonic bonding in order from an endmost leg portion located at one end of the body portion, along the extending direction of the body portion, the misalignment of the leg portions on the circuit patterns increases as the bonding progresses toward the bonding of the other endmost leg portion opposite to the endmost leg portion. Therefore, the lead frame whose leg portions are bonded in this manner needs a large dimensional tolerance with respect to the circuit patterns, which causes difficulty with the manufacturing of a semiconductor device.

### SUMMARY OF THE INVENTION

According to an aspect, there is provided a semiconductor device, including: a semiconductor chip; an insulated circuit substrate including an insulating board, and a circuit pattern disposed on the insulating board and being electrically connected to the semiconductor chip; and a wiring member having a leg portion at one end thereof and an external connection terminal at another end thereof, the leg portion being bonded to the circuit pattern, wherein the leg portion includes a vertical portion, a first divided portion, and a second divided portion, the vertical portion extending in a vertical direction that is orthogonal to a plane of the circuit pattern, and having a split end that is provided at a side of the vertical portion at which the circuit pattern is disposed, the first divided portion extending from the split end in a first direction that is parallel to the plane of the circuit pattern and being bonded to the circuit pattern, the second divided portion extending from the split end in a second direction opposite the first direction and being bonded to the circuit pattern.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of the inside of a semiconductor device according to a first embodiment;

FIGS. 2A and 2B are views for describing the semiconductor device according to the first embodiment;

FIG. 3 is a plan view of a ceramic circuit substrate provided in the semiconductor device according to the first embodiment;

FIG. 4 is a plan view of a plurality of ceramic circuit substrates connected with lead frames provided in the semiconductor device according to the first embodiment;

FIG. 5 is a side view of the plurality of ceramic circuit substrates connected with the lead frames provided in the semiconductor device according to the first embodiment;

FIG. 6 is a perspective view of a leg portion of a lead frame provided in the semiconductor device according to the first embodiment;

FIG. 7 is a flowchart illustrating a method of manufacturing the semiconductor device according to the first embodiment;

FIG. 8 is a view for describing an ultrasonic bonding step included in the method of manufacturing the semiconductor device according to the first embodiment;

FIG. 9 is a perspective view of a leg portion of a lead frame provided in a semiconductor device according to the second embodiment; and

FIGS. 10A and 10B are views for describing another type of leg portion of a lead frame provided in the semiconductor device according to the second embodiment.

### DETAILED DESCRIPTION OF THE INVENTION

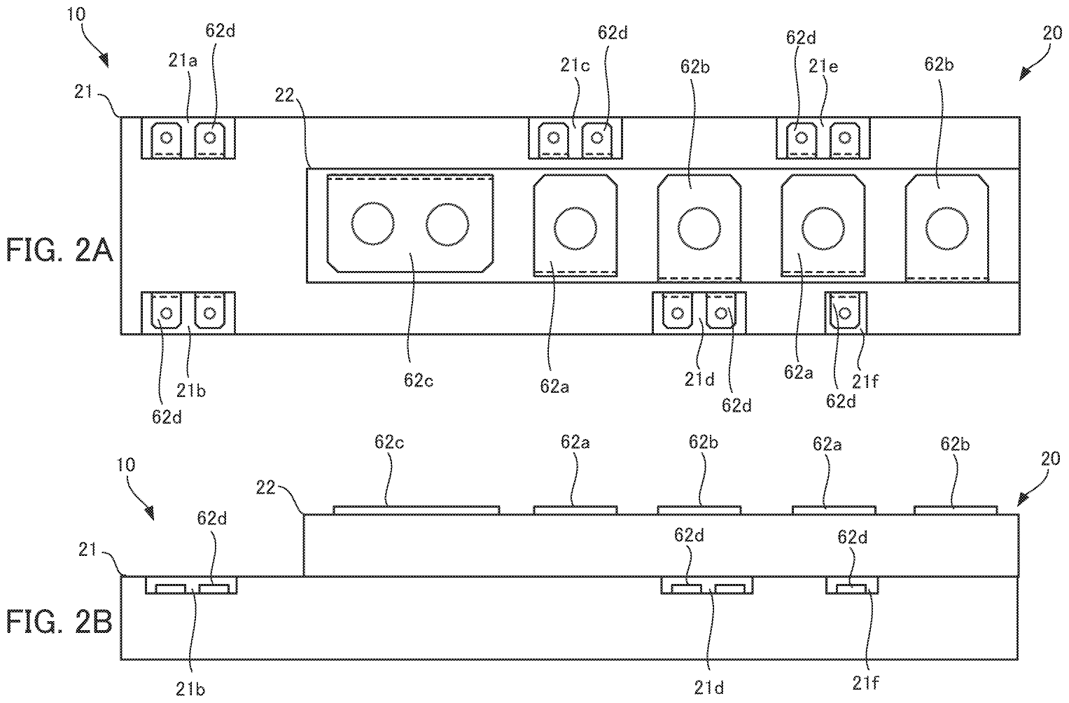

Hereinafter, several embodiments will be described with reference to the accompanying drawings. In the following description, the terms “front surface” and “upper surface” refer to surfaces facing up in a semiconductor device 10 of FIGS. 2A and 2B. Similarly, the term “up” refers to an upward direction in the semiconductor device 10 of FIGS. 2A and 2B. The terms “rear surface” and “lower surface” refer to surfaces facing down in the semiconductor device 10 of FIGS. 2A and 2B. Similarly, the term “down” refers to a downward direction in the semiconductor device 10 of FIGS. 2A and 2B. The same directionality applies to the other drawings as needed. The terms “front surface,” “upper surface,” “up,” “rear surface,” “lower surface,” “down,” and “side surface” are used for convenience to describe relative positional relationships, and do not limit the technical ideas of the embodiments. For example, the terms “up” and “down” are not always related to the vertical direction with respect to the ground. That is, the “up” and “down” directions are not limited to the gravity direction.

### First Embodiment

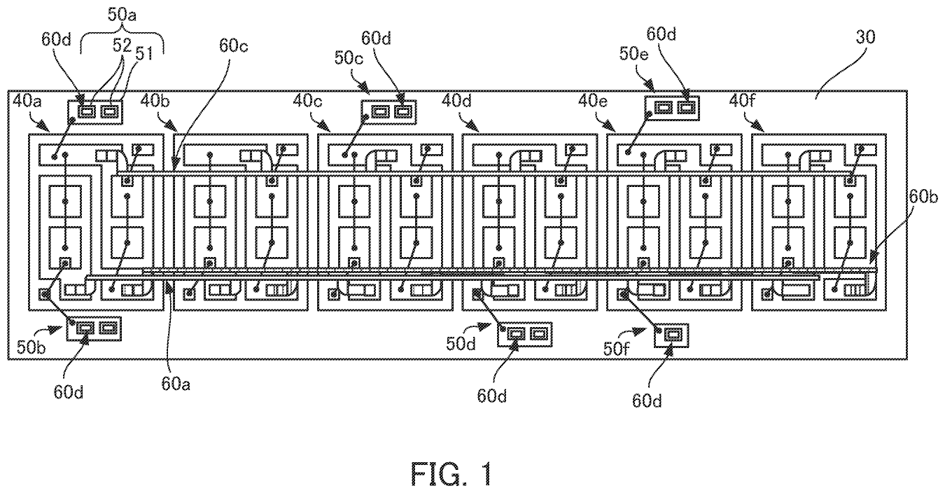

A semiconductor device 10 of a first embodiment will be described with reference to FIGS. 1 and 2. FIG. 1 is a plan view of the inside of the semiconductor device according to the first embodiment. FIGS. 2A and 2B are views for describing the semiconductor device according to the first embodiment. FIG. 1 is a plan view of the semiconductor device 10 of FIGS. 2A and 2B with a case 20 removed. FIG. 2A is a plan view of the semiconductor device 10, and FIG. 2B is a side view of the semiconductor device 10 of FIG. 2A as viewed from below in FIG. 2A.

As illustrated in FIG. 1, the semiconductor device 10 includes a heat dissipation base plate 30, and a plurality of ceramic circuit substrates 40a to 40f and a plurality of control wiring units 50a to 50f that are disposed on the heat dissipation base plate 30. In the following description, the term “ceramic circuit substrate 40” may be used to refer to each individual of the ceramic circuit substrates 40a to 40f without distinction among them. Similarly, the term “control wiring unit 50” may be used to refer to each individual of the control wiring units 50a to 50f without distinction among them. The semiconductor device 10 also has a positive electrode lead frame 60a, a negative electrode lead frame 60b, and an output lead frame 60c, which are electrically connected to the individual ceramic circuit substrates 40. The term “lead frame 60” may be used to refer to each individual of the positive electrode, negative electrode, and output lead frames 60a to 60c without distinction among them. In this semiconductor device 10, a case 20 is attached to the heat dissipation base plate 30 (see FIGS. 2A and 2B). The ceramic circuit substrate 40 and control wiring unit 50 on the heat dissipation base plate 30 are covered with the case 20.

The ceramic circuit substrates 40a to 40f are aligned along the long side of the heat dissipation base plate 30 on the front surface of the heat dissipation base plate 30. The ceramic circuit substrate 40 is bonded to the front surface of the heat dissipation base plate 30 with a solder or silver solder, for example. First semiconductor chips 45a and 46a and second semiconductor chips 45b and 46b, which will be described later, are bonded to each of the ceramic circuit substrates 40a to 40f, and are electrically connected with bonding wires. The bonding wires are made of a material with high electrical conductivity. Examples of the material include gold, silver, copper, aluminum, and an alloy containing at least one of these. The diameters of the bonding wires are in the range of 100 μm to 500 μm, inclusive, for example. The ceramic circuit substrate 40, first semiconductor chips 45a and 46a, and second semiconductor chips 45b and 46b will be described in detail later.

The control wiring units 50a, 50c, and 50e are disposed on the heat dissipation base plate 30 and are located above the ceramic circuit substrates 40a, 40c, and 40e as viewed in FIG. 1. The control wiring units 50b, 50d, and 50f are disposed on the heat dissipation base plate 30 and are located below the ceramic circuit substrates 40a, 40d, and 40e as viewed in FIG. 1. The control wiring unit 50 includes an insulating board 51, a circuit pattern 52 formed on the insulating board 51, and a control lead frame 60d bonded onto the circuit pattern 52. In this connection, the control wiring unit 50f of the control wiring units 50 has one set of circuit pattern 52 and control lead frame 60d. The others of the control wiring units 50 each have two sets of circuit pattern 52 and control lead frame 60d.

The insulating board 51 is made of ceramics with high thermal conductivity. For example, such ceramics are made of a composite material containing, as a principal component, a mixture of aluminum oxide and zirconium oxide, which is added to the aluminum oxide, or a material containing silicon nitride as a principal component. The thickness of the insulating board 51 is in the range of 0.5 mm to 2.0 mm, inclusive. The insulating board 51 is rectangular in plan view. The corners of the insulating board 51 may be chamfered in an R- or C-shape.

The plurality of circuit patterns 52 are made of a metal with high electrical conductivity. Examples of the metal include silver, copper, nickel, and an alloy containing at least one of these. The thicknesses of the plurality of circuit patterns 52 are in the range of 0.5 mm to 1.5 mm, inclusive. Plating may be performed on the surfaces of the plurality of circuit patterns 52 to improve their corrosion resistance. Examples of the plating material used here include nickel, a nickel-phosphorus alloy, and a nickel-boron alloy. The plurality of circuit patterns 52 are formed on the insulating board 51 by forming a metal plate on the front surface of the insulating board 51 and performing etching or another on the metal plate. Alternatively, the plurality of circuit patterns 52 may be cut out from a metal plate in advance and press-bonded to the front surface of the insulating board 51. In this connection, the plurality of circuit patterns 52 illustrated in FIG. 1 are just an example. The number of circuit patterns 52 and the shapes and sizes thereof may be determined according to necessity.

The control lead frames 60d are made of a metal with high electrical conductivity. Examples of the metal include silver, copper, nickel, and an alloy containing at least one of these. Plating may be performed on the surfaces of the control lead frames 60d to improve their corrosion resistance. Examples of the plating material used here include nickel, a nickel-phosphorus alloy, and a nickel-boron alloy. In addition, a control external connection terminal 62d is provided at the end of each control lead frame 60d.

As with the control lead frames 60d, the positive electrode, negative electrode, and output lead frames 60a to 60c are made of a metal with high electrical conductivity, and plating may be performed thereon. Two positive electrode external connection terminals 62a are connected to the positive electrode lead frame 60a. Two negative electrode external connection terminals 62b are connected to the negative electrode lead frame 60b. One output external connection terminal 62c is connected to the output lead frame 60c.

The heat dissipation base plate 30 is made of a metal with high thermal conductivity. Examples of the metal include aluminum, iron, silver, copper, and an alloy containing at least one of these. Plating may be performed on the surface of the heat dissipation base plate 30 to improve its corrosion resistance. Examples of the plating material used here include nickel, a nickel-phosphorus alloy, and a nickel-boron alloy. A cooling unit (not illustrated) may be attached to the rear surface of the heat dissipation base plate 30 of the semiconductor device 10 via a thermal grease. By doing so, the heat dissipation property is improved. For example, the thermal grease is silicone mixed with a metal oxide filler. For example, the cooling unit in this case is made of a material with high thermal conductivity, such as aluminum, iron, silver, copper, or an alloy containing at least one of these. In addition, as the cooling unit, a fin, a heat sink with a plurality of fins, or a cooling device using cool water may be used. The heat dissipation base plate 30 may integrally be formed with such a cooling unit. In this case, a material with high thermal conductivity is used, such as aluminum, iron, silver, copper, or an alloy containing at least one of these. In order to improve the corrosion resistance, for example, plating may be performed on the surface of the heat dissipation base plate 30 integrally formed with the cooling unit using a plating material such as nickel. More specifically, other than nickel, a nickel-phosphorus alloy, a nickel-boron alloy, and the like are used as the plating material.

The case 20 includes a lower housing part 21 and an upper housing part 22. The lower housing part 21 is rectangular in plan view and has a box shape. The upper housing part 22 is rectangular in plan view as well and has a smaller box shape than the lower housing part 21. The lower housing part 21 and upper housing part 22 are integrally connected to each other and have a hollow inside. The case 20 accommodates, in its hollow, the ceramic circuit substrate 40, the positive electrode, negative electrode, output, and control lead frames 60a to 60d, and others. This case 20 is made of a thermoplastic resin. Examples of the resin include a polyphenylene sulfide resin, a polybutyrene terephthalate resin, a polybutylene succinate resin, a polyamide resin, and an acrylonitrile-butadiene-styrene resin.

Control terminal regions 21a, 21c, and 21e that are recessed toward the rear surface of the case 20 are provided along one long side of the front surface of the lower housing part 21. The control external connection terminals 62d of the control lead frames 60d are exposed in the control terminal regions 21a, 21c, and 21e. Control terminal regions 21b, 21d, and 21f that are recessed toward the rear surface of the case 20 are provided along the other long side of the front surface of the lower housing part 21. The control external connection terminals 62d of the control lead frames 60d are exposed in the control terminal regions 21b, 21d, and 21f. The output external connection terminal 62c, positive electrode external connection terminal 62a, negative electrode external connection terminal 62b, positive electrode external connection terminal 62a, and negative electrode external connection terminal 62b are exposed along the long side of the upper housing part 22 on the front surface of the upper housing part 22. In this connection, the output external connection terminal 62c has a flat plate shape, and is caused to extend vertically upward from the one long side of the front surface of the upper housing part 22 and is bent to lie on the front surface of the upper housing part 22. The positive electrode external connection terminal 62a, negative electrode external connection terminal 62b, positive electrode external connection terminal 62a, and negative electrode external connection terminal 62b have a flat plate shape as well, and are caused to extend vertically upward from the other long side of the front surface of the upper housing part 22 and are bent to lie on the front surface of the upper housing part 22.

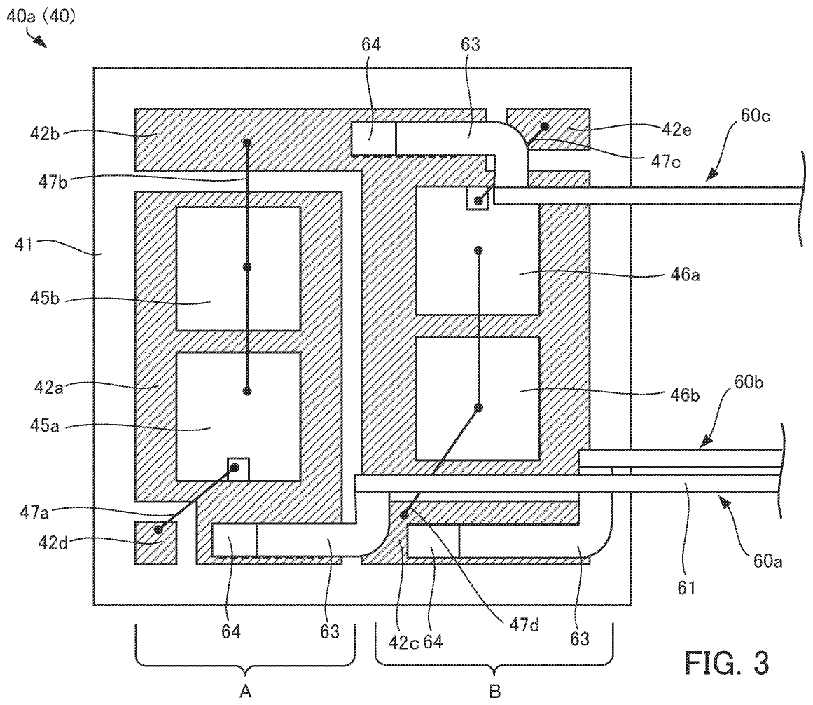

The following describes the ceramic circuit substrate 40 with reference to FIG. 3. FIG. 3 is a plan view of a ceramic circuit substrate provided in the semiconductor device according to the first embodiment. In this connection, FIG. 3 illustrates the ceramic circuit substrate 40a, and the other ceramic circuit substrates have the same configuration.

On the ceramic circuit substrate 40a, the first semiconductor chips 45a and 46a and second semiconductor chips 45b and 46b are disposed and are connected with bonding wires 47a to 47d. The first semiconductor chips 45a and 46a are switching elements that are made of silicon or silicon carbide. The switching elements may be IGBTs or power MOSFETs, for example. In the case where each first semiconductor chip 45a and 46a is an IGBT, it has a collector electrode serving as a main electrode on the rear surface thereof and has a gate electrode serving as a control electrode and an emitter electrode serving as a main electrode on the front surface thereof. In the case where each first semiconductor chip 45a and 46a is a power MOSFET, it has a drain electrode serving as a main electrode on the rear surface thereof and has a gate electrode serving as a control electrode and a source electrode serving as a main electrode on the front surface thereof. The second semiconductor chips 45b and 46b are diode elements that are made of silicon or silicon carbide. The diode elements are free wheeling diodes (FWDs) such as Schottky barrier diodes (SBDs) and P-intrinsic-N (PiN) diodes. Each second semiconductor chip 45b and 46b has a cathode electrode serving as a main electrode on the rear surface thereof and has an anode electrode serving as a main electrode on the front surface thereof. The rear surfaces of the first semiconductor chips 45a and 46a and second semiconductor chips 45b and 46b are bonded to the predetermined circuit patterns 42a and 42b with a solder (not illustrated). A lead-free solder is used as the solder. For example, the lead-free solder contains, as a principal component, at least one of a tin-silver-copper alloy, a tin-zinc-bismuth alloy, a tin-copper alloy, and a tin-silver-indium-bismuth alloy. In addition, the solder may contain an additive. Examples of the additive include nickel, germanium, cobalt, and silicon. The addition of such an additive allows the solder to provide improved wettability, gloss, and bond strength, which results in an improvement in the reliability. A sintered metal may be used instead of the solder. In addition, the thicknesses of the first semiconductor chips 45a and 46a and second semiconductor chips 45b and 46b are in the range of 180 μm to 220 μm, inclusive, and are approximately 200 μm on average.

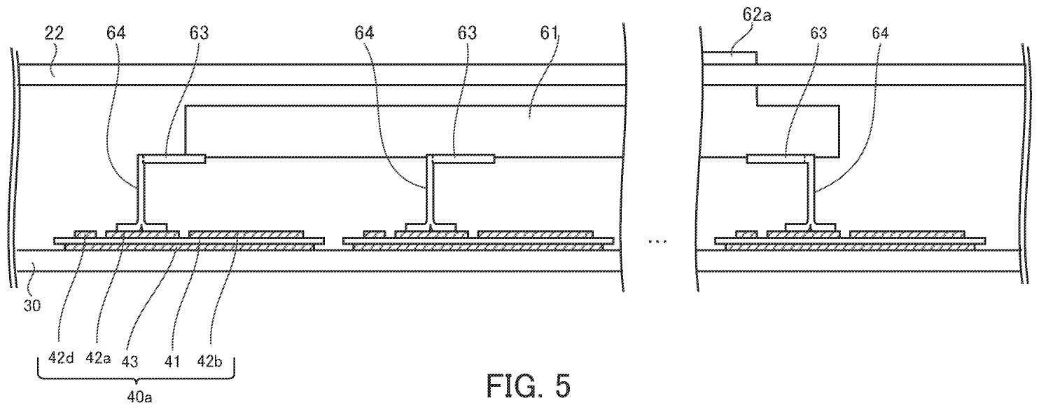

The ceramic circuit substrate 40a includes an insulating board 41 and a metal plate 43 (see FIG. 5) formed on the rear surface of the insulating board 41. In addition, the ceramic circuit substrate 40a includes circuit patterns 42a to 42e formed on the front surface of the insulating board 41. In the following description, the term “circuit pattern 42” may be used to refer to each individual of the circuit patterns 42a to 42e without distinction among them. Similar to the insulating board 51, the insulating board 41 is made of ceramics with high thermal conductivity, such as aluminum oxide, aluminum nitride, or silicon nitride that has high thermal conductivity. The metal plate 43 is made of a metal with high thermal conductivity, such as aluminum, iron, silver, copper, or an alloy containing at least one of these. Similar to the circuit pattern 52, the circuit patterns 42a to 42e are made of a metal with high electrical conductivity, such as copper or a copper alloy. To improve the corrosion resistance, for example, plating may be performed on their surfaces using a material such as nickel. More specifically, other than nickel, a nickel-phosphorus alloy and a nickel-boron alloy may be used. The thicknesses of the circuit patterns 42a to 42e are in the range of 0.1 mm to 1 mm, inclusive, for example. In addition, for the ceramic circuit substrate 40a configured as above, a direct copper bonding (DCB) substrate or an active metal brazed (AMB) substrate may be used, for example. In the ceramic circuit substrate 40a, heat generated by the first and second semiconductor chips 45a and 45b is transferred to the heat dissipation base plate 30 via the circuit patterns 42a and 42b, insulating board 41, and metal plate 43.

The circuit pattern 42a forms a collector pattern of a first arm part A. The collector electrodes formed on the rear surfaces of the first and second semiconductor chips 45a and 45b are bonded to the circuit pattern 42a via a solder. The circuit pattern 42a is approximately rectangular, having a projection at a lower part thereof as viewed in FIG. 3 to which a leg portion 64 of the positive electrode lead frame 60a is bonded. The circuit pattern 42d forms a control pattern of the first arm part A. A bonding wire 47a connecting to the gate electrode of the first semiconductor chip 45a is connected to the circuit pattern 42d. In addition, the circuit pattern 42d is electrically connected to the control wiring unit 50b with a bonding wire (not illustrated).

The circuit pattern 42b forms an emitter pattern of the first arm part A and a collector pattern of a second arm part B. A bonding wire 47b connecting to the output electrodes (emitter electrodes) of the first semiconductor chips 45a and 45b on the circuit pattern 42a is connected to the circuit pattern 42b. In addition, the collector electrodes formed on the rear surfaces of the first and second semiconductor chips 46a and 46b are bonded to the circuit pattern 42b with a solder. The circuit pattern 42b is approximately rectangular, having a projection at an upper part thereof as viewed in FIG. 3. The circuit pattern 42b and circuit pattern 42a are disposed side by side. In addition, the circuit pattern 42b is electrically connected to the control wiring unit 50a with a bonding wire (not illustrated). The circuit pattern 42e forms a control pattern of the second arm part B. A bonding wire 47c connecting to the gate electrode of the first semiconductor chip 46a is connected to the circuit pattern 42e.

The circuit pattern 42c forms an emitter pattern of the second arm part B. A bonding wire 47d connecting to the output electrodes (emitter electrodes) of the first and second semiconductor chips 46a and 46b is connected to the circuit pattern 42c. The circuit pattern 42c is disposed below the circuit pattern 42b as viewed in FIG. 3. A leg portion 64 of the negative electrode lead frame 60b is bonded to the circuit pattern 42c.

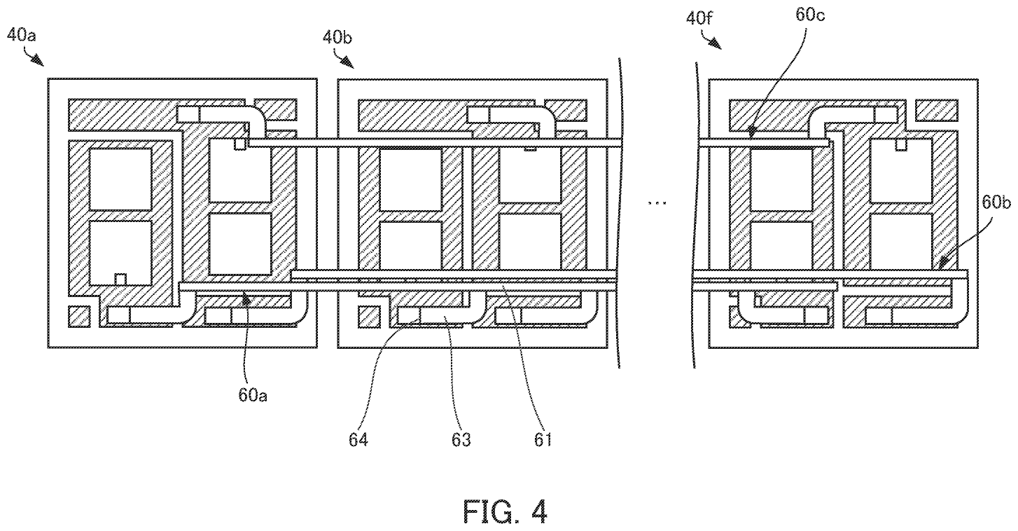

In the semiconductor device 10, a plurality of ceramic circuit substrates 40 each having the first semiconductor chips 45a and 46a and second semiconductor chips 45b and 46b bonded thereto as described above are disposed along the long-side direction of the heat dissipation base plate 30 on the front surface of the heat dissipation base plate 30. In addition, the positive electrode, negative electrode, and output lead frames 60a to 60c are electrically connected to the plurality of ceramic circuit substrates 40 as appropriate. The plurality of ceramic circuit substrates 40 and positive electrode, negative electrode, and output lead frames 60a to 60c will be described with reference to FIGS. 4 and 5. FIG. 4 is a plan view of the plurality of ceramic circuit substrates connected with lead frames provided in the semiconductor device according to the first embodiment. FIG. 5 is a side view of the plurality of ceramic circuit substrates connected with the lead frames provided in the semiconductor device according to the first embodiment. In this connection, the heat dissipation base plate 30 is not illustrated in FIG. 4. FIG. 5 illustrates a side view of only the positive electrode lead frame 60a. In addition, FIG. 5 illustrates part of the upper housing part 22 of the case 20.

As illustrated in FIGS. 4 and 5, the positive electrode, negative electrode, and output lead frames 60a to 60c are electrically bonded to the ceramic circuit substrates 40a to 40f arranged in one direction as appropriate. The positive electrode lead frame 60a has a body portion 61, the positive electrode external connection terminals 62a, interlinking portions 63, and leg portions 64. The positive electrode lead frame 60a has the leg portions 64 (and the interlinking portions 63) at positions of the body portion 61 corresponding to the individual ceramic circuit substrates 40 connected thereto. The positive electrode lead frame 60a also has the positive electrode external connection terminals 62a at positions of the body portion 61 corresponding to where the positive electrode external connection terminals 62a are exposed from the case 20. Similarly, the negative electrode and output lead frames 60b and 60c each have leg portions 64 (and interlinking portions 63) at positions of its body portion 61 corresponding to the individual ceramic circuit substrates 40 connected thereto. The negative electrode and output lead frames 60b and 60c respectively have the negative electrode external connection terminals 62b and the output external connection terminal 62c, not illustrated in FIGS. 4 and 5, at positions of their body portions 61 corresponding to where the negative electrode and output external connection terminals 62b and 62c are exposed from the case 20 as illustrated in FIGS. 2A and 2B.

The body portion 61 has a flat plate shape, and extends in a wiring direction at a predetermined height measured from the front surfaces of the plurality of ceramic circuit substrates 40 arranged in one direction, as illustrated in FIGS. 4 and 5. The positive electrode, negative electrode, and output external connection terminals 62a to 62c have a flat plate shape, and are integrally connected to the corresponding body portions 61 such as to project in a vertical direction with respect to the front surface of the ceramic circuit substrate 40. In this connection, the positive electrode, negative electrode, and output external connection terminals 62a to 62c are disposed to face the front surface of the upper housing part 22 of the case 20. When the case 20 is attached to the heat dissipation base plate 30, the positive electrode, negative electrode, and output external connection terminals 62a to 62c extend in a vertical direction from the front surface of the upper housing part 22 of the case 20. By bending the positive electrode, negative electrode, and output external connection terminals 62a to 62c extending from the front surface of the upper housing part 22 of the case 20, the principal surfaces of the positive electrode, negative electrode, and output external connection terminals 62a to 62c are exposed on the front surface of the upper housing part 22 as illustrated in FIGS. 2A and 2B.

With regard to each positive electrode, negative electrode, and output lead frame 60a to 60c, the leg portions 64 are bonded to and electrically connected to the circuit patterns 42a to 42c of the ceramic circuit substrate 40. The leg portions 64 will be described in detail later. The interlinking portions 63 are integrally connected to the body portion 61 and the corresponding leg portions 64. In this connection, each interlinking portion 63 electrically connects the body portion 61 and the corresponding leg portion 64.

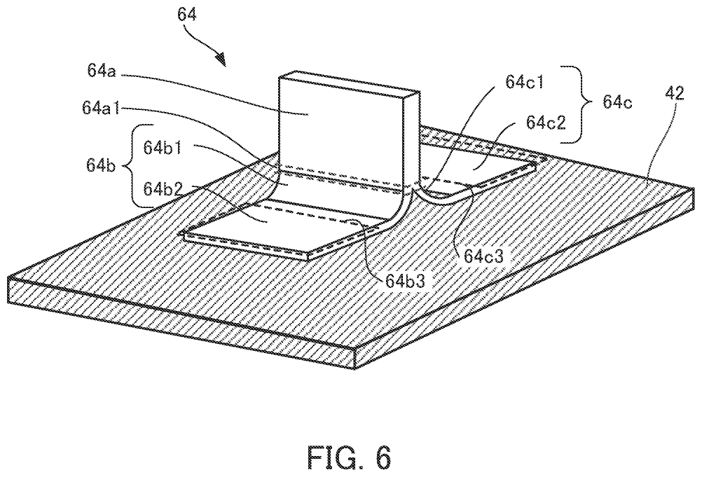

The following describes the leg portions 64 of the positive electrode, negative electrode, and output lead frames 60a to 60c with respect to FIG. 6. FIG. 6 is a perspective view of a leg portion of a lead frame provided in the semiconductor device according to the first embodiment. FIG. 6 illustrates a leg portion 64 (the lower end thereof) of the lead frame 60, which is bonded to the circuit pattern 42. The body portion 61 and interlinking portion 63 of the lead frame 60 are not illustrated.

The leg portion 64 includes a vertical portion 64a and divided portions 64b and 64c. The vertical portion 64a and the divided portions 64b and 64c of the leg portion 64 are all equal in width. The thicknesses of the divided portions 64b and 64c are preferably half the thickness of the vertical portion 64a, as will be described later. That is, the total thickness of the divided portions 64b and 64c is equal to the thickness of the vertical portion 64a. The vertical portion 64a extends in a vertical direction with respect to the circuit pattern 42. The vertical portion 64a connects to the interlinking portion 63 at the extending end of the vertical portion 64a. The divided portion 64b includes a continuing portion 64b1 and a parallel portion 64b2. The continuing portion 64b1 is bent in a predetermined direction (bent direction) from a split part (split end) 64a1 that is provided at the bottom end of the vertical portion 64a on the side where the circuit pattern 42a is disposed. The predetermined direction is a thickness direction. In other words, the predetermined direction is a direction of separating the divided portion 64b after splitting the other end opposite to one end (vertical portion 64a) sandwiched as described later from a dividing line formed at the other end so as to cross the other end in parallel to the width direction. The parallel portion 64b2 continues from the continuing portion 64b1 and extends in parallel to the circuit pattern 42, and a circuit pattern bonding region 64b3 provided on the rear surface of the parallel portion 64b2 is bonded to the circuit pattern 42. On the other hand, the divided portion 64c is disposed opposite to the divided portion 64b and includes a continuing portion 64c1 and a parallel portion 64c2. The continuing portion 64c1 is bent in a direction opposite to the predetermined direction from the split part 64a1 that is provided at the bottom end of the vertical portion 64a on the side where the circuit pattern 42 is disposed. The parallel portion 64c2 continues from the continuing portion 64c1 and extends in parallel to the circuit pattern 42, and a circuit pattern bonding region 64c3 provided on the rear surface of the parallel portion 64c2 is bonded to the circuit pattern 42.

Connected to the body portion 61 via the interlinking portion 63, the above leg portion 64 is attached to the circuit pattern 42 in such a manner that the predetermined direction with respect to the divided portions 64b and 64c is parallel to the wiring direction of the body portion 61. In the leg portion 64, the length from the split part 64a1 to an end of the divided portion 64b in the predetermined direction is equal to the length from the split part 64a1 to an end of the divided portion 64c in the direction opposite to the predetermined direction. In addition, since the divided portions 64b and 64c are equal in width, they are equal in area, and especially the parallel portions 64b2 and 64c2 are equal in area.

In addition, the above leg portion 64 is obtained as follows: one end (vertical portion 64a) of a conductive plate that has a rectangular plate shape is sandwiched and fixed, a dividing line is formed at the other end of the conductive plate so as to cross the width in parallel to the width direction, the conductive plate is split from the dividing line to form divided portions, and the divided portions are bent in opposite directions. Therefore, the thickness of the vertical portion 64a is equal to the total thickness of the divided portions 64b and 64c. At this time, the thickness of each divided portion 64b and 64c is preferably half the thickness of the vertical portion 64a. In thus obtained leg portion 64, the divided portions 64b and 64c are bonded to the circuit pattern 42. As described later, the divided portions 64b and 64c are bonded to the circuit pattern 42 by ultrasonic bonding. Therefore, each divided portion 64b and 64c and the circuit pattern 42 are bonded directly to each other, without any bonding member therebetween. The leg portion 64 is bonded to the circuit pattern 42 stably. In addition, the front surface side and back surface side of the vertical portion 64a are supported stably and firmly by the divided portions 64b and 64c, respectively. In addition, the continuing portions 64b1 and 64c1 are not bonded to the circuit pattern 42 and provides elasticity between the vertical portion 64a and the divided portions 64b and 64c. Therefore, the continuing portions 64b1 and 64c1 are able to absorb shock caused by the outside to the leg portion 64. This prevent deformation, misalignment, and others of the vertical portion 64a and thus keeps the lead frame 60 at the predetermined bonding position.

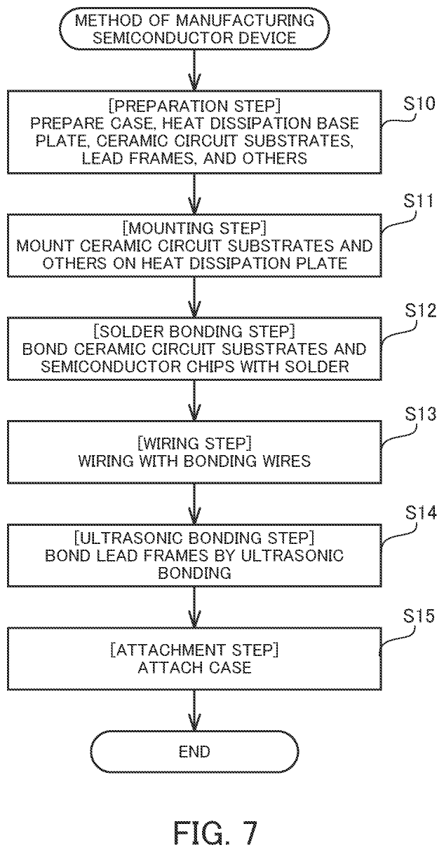

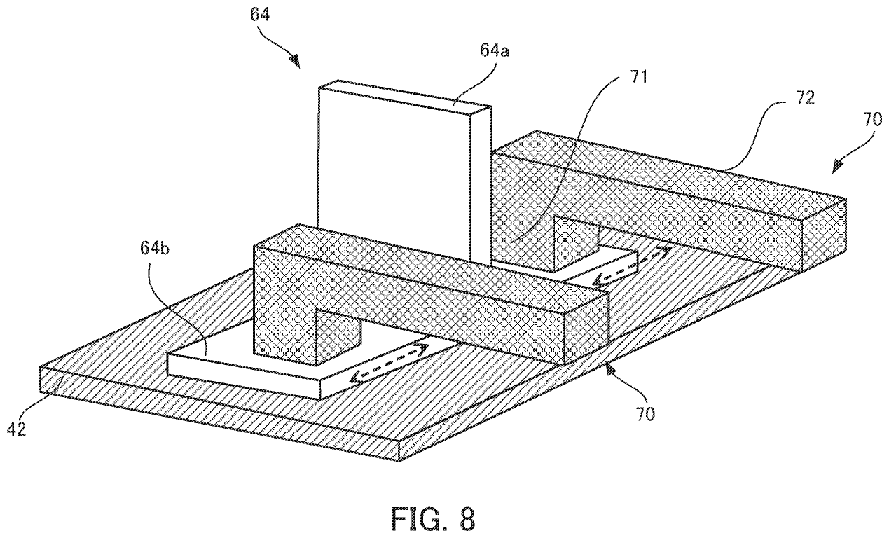

The following describes a method of manufacturing the semiconductor device 10 including the leg portions 64 bonded to the circuit pattern 42 as described above, with reference to FIGS. 7 and 8. FIG. 7 is a flowchart illustrating a method of manufacturing the semiconductor device according to the first embodiment. FIG. 8 is a view for describing an ultrasonic bonding step included in the method of manufacturing the semiconductor device according to the first embodiment.

First, a preparation step of preparing the case 20, heat dissipation base plate 30, ceramic circuit substrate 40, control wiring units 50a to 50e, first semiconductor chips 45a and 46a, second semiconductor chips 45b and 46b, lead frame 60, and others is performed (step S10 in FIG. 7). At this time, the leg portions 64 illustrated in FIG. 6 are formed in the lead frame 60 in advance.

Then, a mounting step is performed as follows (step S11 in FIG. 7). The ceramic circuit substrate 40 and control wiring units 50a to 50e are mounted at predetermined positions on the front surface of the heat dissipation base plate 30 via a solder. In addition, the first semiconductor chips 45a and 46a and second semiconductor chips 45b and 46b are mounted on the circuit pattern 42 of the ceramic circuit substrate 40 via the solder.

Then, a solder bonding step is performed as follows in the situation where step S11 is complete (step S12 in FIG. 7). First, heat treatment is performed to melt the solder. After the solder is melt, cooling treatment is performed to solidify the solder. By doing so, the ceramic circuit substrate 40 and control wiring units 50a to 50e are bonded to the heat dissipation base plate 30 with the solder. In addition, the first semiconductor chips 45a and 46a and second semiconductor chips 45b and 46b are bonded to the circuit pattern 42 of the ceramic circuit substrate 40 with the solder.

Then, a wiring step of electrically connecting the ceramic circuit substrate 40, first semiconductor chips 45a and 46a, and second semiconductor chips 45b and 46b with bonding wires is performed (step S13 in FIG. 7). Then, an ultrasonic bonding step of bonding the leg portions 64 of the lead frame 60 to the circuit pattern 42 of the ceramic circuit substrate 40 by ultrasonic bonding is performed (step S14 in FIG. 7). An ultrasonic bonding device is used for the ultrasonic bonding. The ultrasonic bonding device includes an ultrasonic generator and ultrasonic tools 70 that propagate ultrasonic waves generated by the ultrasonic generator and are illustrated in FIG. 8. First, the circuit pattern bonding regions 64b3 and 64c3 of the parallel portions 64b2 and 64c2 of a leg portion 64 are disposed at bonding positions of a circuit pattern 42. The two ultrasonic tools 70 of the ultrasonic bonding device are set on the parallel portions 64b2 and 64c2 of the leg portion 64, respectively, as illustrated in FIG. 8. Each ultrasonic tool 70 is L-shaped and includes a pressing portion 71 and a propagation portion 72 connected to the pressing portion 71. The pressing portion 71 has a flat surface that is made in contact with the front side of a parallel portion 64b2 or 64c2 of the leg portion 64. One end of the propagation portion 72 is connected to the pressing portion 71 and the other end thereof is connected to the ultrasonic generator. The propagation portion 72 propagates ultrasonic waves generated by the ultrasonic generator to the pressing portion 71.

The pressing portions 71 of these ultrasonic tools 70 press the parallel portions 64b2 and 64c2 of the leg portion 64 toward the circuit pattern 42 while vibrating them simultaneously. In doing so, the ultrasonic vibration deforms the parallel portions 64b2 and 64c2 simultaneously in parallel to the vibrating direction (for example, the bending directions of the divided portions 64b and 64c) (for example, in the directions indicated by the bidirectional dashed arrow of FIG. 8). Here, the parallel portions 64b2 and 64c2 are deformed in the vibrating direction in the same way, the parallel portions 64b2 and 64c2 are bonded to the circuit pattern 42 without causing the misalignment of the vertical portion 64a. Even when the leg portions 64 provided in the lead frame 60 are bonded in order from the one to be bonded to the ceramic circuit substrate 40a to the one to be bonded to the ceramic circuit substrate 40f in the manner described above, the misalignment of a leg portion 64 of the lead frame 60 does not increase as the bonding progresses toward the bonding to the ceramic circuit substrate 40f. As a result, the lead frame 60 is bonded at the predetermined bonding positions of the plurality of ceramic circuit substrates 40 properly.

Alternatively, using the pressing portions 71 of the ultrasonic tools 70, the parallel portions 64b2 and 64c2 of the leg portion 64 may be pressed and bonded in the following manner. In the lead frame 60 with the plurality of leg portions 64, the parallel portions 64b2 and 64c2 may alternately be bonded to the ceramic circuit substrate 40 along the body portion 61, from one endmost leg portion 64 to the other endmost leg portion 64, using the ultrasonic tools 70.

An example of this case will be described using the positive electrode lead frame 60a (see FIGS. 4 and 5). First, the parallel portion 64b2 of an endmost leg portion 64 of the positive electrode lead frame 60a is bonded to the ceramic circuit substrate 40a by the ultrasonic bonding, and the parallel portion 64c2 of the leg portion 64 in question are bonded to the ceramic circuit substrate 40a by the ultrasonic bonding. Then, the parallel portion 64b2 of the leg portion 64 next to the endmost leg portion 64 of the positive electrode lead frame 60a is bonded to the ceramic circuit substrate 40b by the ultrasonic bonding, and the parallel portion 64c2 of the leg portion 64 in question is bonded to the ceramic circuit substrate 40b by the ultrasonic bonding. In this manner, in the positive electrode lead frame 60a, each leg portion 64 is bonded to the ceramic circuit substrate 40 along the body portion 61 in order of the parallel portion 64b2 and then the parallel portion 64c2. Finally, the parallel portion 64b2 of the other endmost leg portion 64 of the positive electrode lead frame 60a is bonded to the ceramic circuit substrate 40f by the ultrasonic bonding, and the parallel portion 64c2 of the leg portion 64 in question is bonded to the ceramic circuit substrate 40f by the ultrasonic bonding. In this connection, the parallel portions 64b2 and 64c2 in the plurality of leg portions 64 are not bonded alternately in this order along the body portion 61 of the lead frame 60, but the parallel portions 64c2 and 64b2 in the plurality of leg portions 64 may be bonded alternatively in this order along the body portion 61. In both cases, as in the case where the parallel portions 64b2 and 64c2 of each leg portion 64 are bonded simultaneously, the misalignment does not increase as the bonding progresses toward the bonding to the ceramic circuit substrate 40f even when the leg portions 64 provided in the lead frame 60 are bonded in order from the one to be bonded to the ceramic circuit substrate 40a to the one to be bonded to the ceramic circuit substrate 40f. As a result, the lead frame 60 is bonded at the predetermined bonding positions on the plurality of ceramic circuit substrates 40 properly.

Then, the positive electrode, negative electrode, output, and control external connection terminals 62a to 62d are exposed from the predetermined positions of the case 20 and the case 20 is attached to the heat dissipation base plate 30 using an adhesive (step S15 of FIG. 7). In the manner described above, the semiconductor device 10 of FIGS. 2A and 2B is obtained.

The above-described semiconductor device 10 includes the first semiconductor chips 45a and 46a, second semiconductor chips 45b and 46b, and ceramic circuit substrate 40 having the insulating board 41 and circuit patterns 42 disposed on the insulating board 41 and electrically connected to the first semiconductor chips 45a and 46a and second semiconductor chips 45b and 46b. In addition, the semiconductor device 10 includes the lead frames 60 that each have at one end thereof leg portions 64 bonded to the circuit patterns 42 and at the other end thereof the corresponding ones of the positive electrode, negative electrode, and output external connection terminals 62a to 62c. Each leg portion 64 has the vertical portion 64a and the divided portions 64b and 64c. The vertical portion 64a extends in a vertical direction with respect to the circuit pattern 42. The divided portion 64b is bent in the predetermined direction from the split part 64a1 that is provided at the bottom end of the vertical portion 64a on the side where the circuit pattern 42 is disposed, extends in parallel to the circuit pattern 42, and is bonded to the circuit pattern 42. The divided portion 64c is bent in a direction opposite to the predetermined direction from the split part 64a1, extends in parallel to the circuit pattern 42, and is bonded to the circuit pattern 42.

In each leg portion 64, the front surface side and back surface side of the vertical portion 64a are supported firmly by the divided portions 64b and 64c, respectively. Therefore, the leg portions 64 are bonded to the circuit patterns 42 stably. In addition, each leg portion 64 is divided in the thickness direction, so the divided portions 64b and 64c are thinner than the vertical portion 64a, which allows ultrasonic vibration to propagate to the circuit pattern bonding regions 64b3 and 64c3 of the parallel portions 64b2 and 64c2 to be bonded to the circuit pattern 42 easily, which achieves stronger bonding. In addition, the divided portions 64b and 64c of each leg portion 64 are bonded simultaneously to the circuit pattern 42 by ultrasonic vibration. Since the divided portions 64b and 64c are deformed in parallel to the bending directions in the same way, misalignment of the vertical portion 64a does not occur. Therefore, the lead frame 60 is held at the predetermined bonding position without the misalignment of the vertical portion 64a. As a result, the semiconductor device 10 is manufactured properly.

### Second Embodiment

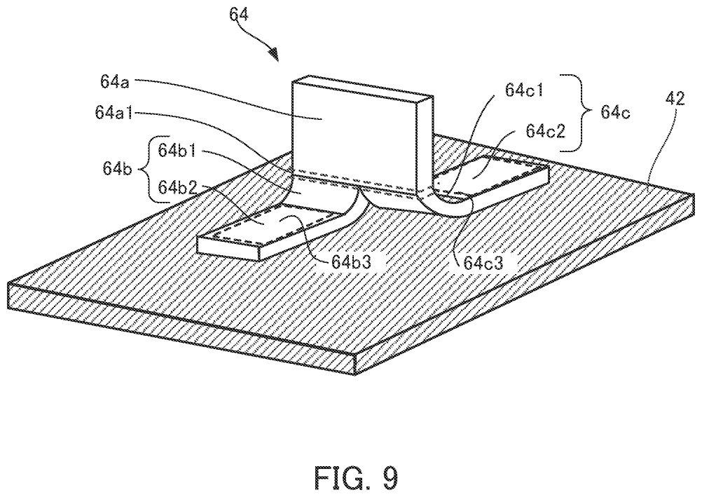

In a second embodiment, leg portions different from those of the first embodiment will be described with reference to FIG. 9. FIG. 9 is a perspective view of a leg portion of a lead frame provided in a semiconductor device according to the second embodiment. Note that FIG. 9 illustrates a leg portion 64 only. The leg portions 64 of the second embodiment are provided in place of the leg portions 64 of the lead frame 60 of the first embodiment. Therefore, except for the leg portions 64, the semiconductor device of the second embodiment has the same configuration as the semiconductor device 10 of the first embodiment.

The leg portion 64 of FIG. 9 includes a vertical portion 64a and divided portions 64b and 64c. The vertical portion 64a extends in a vertical direction with respect to a circuit pattern 42. The vertical portion 64a connects to an interlinking portion 63 at the extending end of the vertical portion 64a. Unlike the first embodiment, the divided portions 64b and 64c are obtained by making one cut in perpendicular to the vertical portion 64a so as to divide the leg portion 64 in the width direction of the vertical portion 64a. Therefore, the total width of the divided portions 64b and 64c is equal to the width of the vertical portion 64a. The divided portion 64b includes a continuing portion 64b1 and a parallel portion 64b2. As in the first embodiment, the continuing portion 64b1 is bent in a predetermined direction from a split part 64a1 that is provided at the bottom end of the vertical portion 64a on the side where the circuit pattern 42 is disposed. The parallel portion 64b2 continues from the continuing portion 64b1 and extends in parallel to the circuit pattern 42, and a circuit pattern bonding region 64b3 provided on the rear surface of the parallel portion 64b2 is bonded to the circuit pattern 42. On the other hand, the divided portion 64c is disposed opposite to the divided portion 64b and includes a continuing portion 64c1 and a parallel portion 64c2. The continuing portion 64c1 is bent in a direction opposite to the predetermined direction from the split part 64a1 that is provided at the bottom end of the vertical portion 64a on the side where the circuit pattern 42 is disposed. The parallel portion 64c2 continues from the continuing portion 64c1 and extends in parallel to the circuit pattern 42, and a circuit pattern bonding region 64c3 provided on the rear surface of the parallel portion 64c2 is bonded to the circuit pattern 42. As in the first embodiment, the parallel portions 64b2 and 64c2 of the leg portion 64 are vibrated and pressed toward the circuit pattern 42 simultaneously or alternately by the pressing portions 71 of the ultrasonic tools 70, thereby achieving the bonding of the leg portion 64.

Connected to a body portion 61 via the interlinking portion 63, the above leg portion 64 is attached to the circuit pattern 42 in such a manner that the predetermined direction with respect to the divided portions 64b and 64c are parallel to the wiring direction of the body portion 61. In the leg portion 64, the length from the split part 64a1 to an end of the divided portion 64b in the predetermined direction is equal to the length from the split part 64a1 to an end of the divided portion 64c in the direction opposite to the predetermined direction. In addition, in the case where the cut between the divided portions 64b and 64c is at a position halving the width of the vertical portion 64a, the divided portions 64b and 64c are equal in width and are therefore equal in area, and especially the parallel portions 64b2 and 64c2 are equal in area.

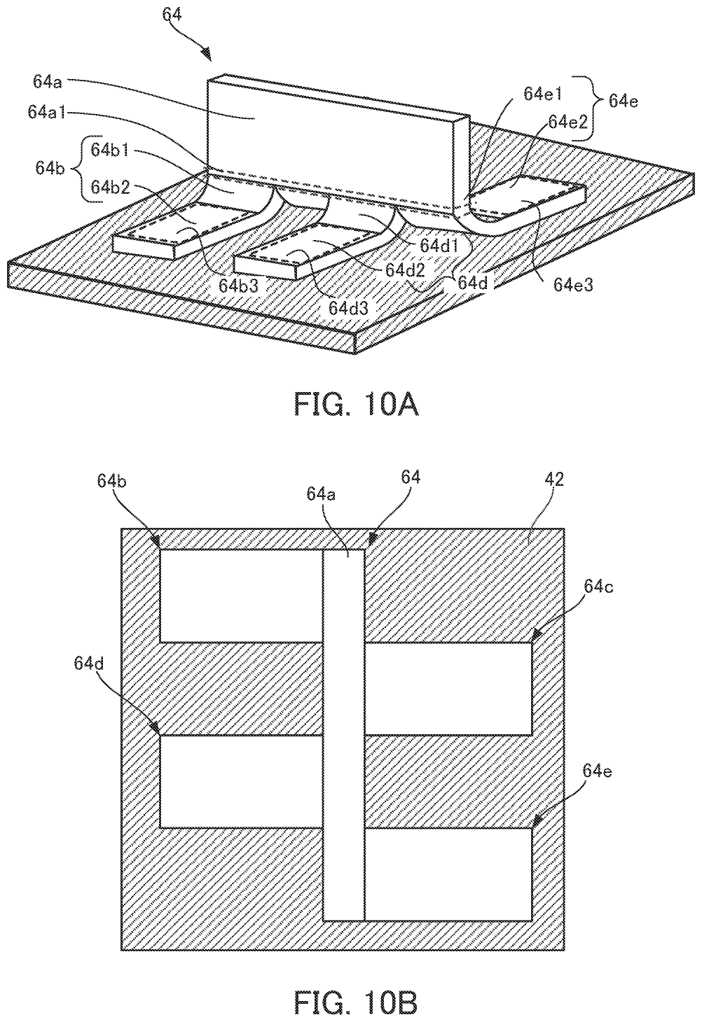

Another type of leg portion of the second embodiment will be described with reference to FIGS. 10A and 10B. FIGS. 10A and 10B are views for describing another type of leg portion of a lead frame provided in the semiconductor device according to the second embodiment. FIG. 10A illustrates a perspective view of the leg portion 64, whereas FIG. 10B illustrates a plan view of the leg portion 64. Note that a divided portion 64c is disposed behind the vertical portion 64a and is not illustrated in of FIG. 10A.

The leg portion 64 of FIGS. 10A and 10B includes a vertical portion 64a and divided portions 64b to 64e. The vertical portion 64a extends in a vertical direction with respect to the circuit pattern 42. The vertical portion 64a connects to the interlinking portion 63 at the extending end of the vertical portion 64a. Unlike the first embodiment, the divided portions 64b to 64e are obtained by making three cuts in perpendicular to the vertical portion 64a so as to divide the leg portion 64 at equal intervals in the width direction of the vertical portion 64a. Therefore, the total width of the divided portions 64b to 64e is equal to the width of the vertical portion 64a. That is, the leg portion 64 illustrated in FIGS. 10A and 10B includes two pairs of divided portions 64b and 64c of the leg portion 64 illustrated in FIG. 9. In this connection, the leg portion 64 illustrated in FIGS. 10A and 10B includes two pairs of divided portions, but may include three or more pairs of divided portions.

The divided portion 64b includes a continuing portion 64b1 and a parallel portion 64b2. The continuing portion 64b1 is bent in a predetermined direction from a split part 64a1 that is provided at the bottom end of the vertical portion 64a on the side where the circuit pattern 42 is disposed. The parallel portion 64b2 continues from the continuing portion 64b1 and extends in parallel to the circuit pattern 42, and a circuit pattern bonding region 64b3 provided on the rear surface of the parallel portion 64b2 is bonded to the circuit pattern 42. Similarly, the divided portion 64d includes a continuing portion 64d1 and a parallel portion 64d2. The continuing portion 64d1 is bent in the predetermined direction from the split part 64a1 that is provided at the bottom end of the vertical portion 64a on the side where the circuit pattern 42 is disposed. The parallel portion 64d2 continues from the continuing portion 64d1 and extends in parallel to the circuit pattern 42, and a circuit pattern bonding region 64d3 provided on the rear surface of the parallel portion 64d2 is bonded to the circuit pattern 42.

On the other hand, the divided portion 64c is disposed at the opposite side of the divided portions 64b and 64d across the vertical portion 64a and includes a continuing portion 64c1 and a parallel portion 64c2 (see FIG. 9). The continuing portion 64c1 is bent in a direction opposite to the predetermined direction from the split part 64a1 that is provided at the bottom end of the vertical portion 64a on the side where the circuit pattern 42 is disposed. The parallel portion 64c2 continues from the continuing portion 64c1 and extends in parallel to the circuit pattern 42, and a circuit pattern bonding region 64c3 provided on the rear surface of the parallel portion 64c2 is bonded to the circuit pattern 42. In addition, the divided portion 64e is disposed at the opposite side of the divided portions 64b and 64d across the vertical portion 64a and includes a continuing portion 64e1 and a parallel portion 64e2. The continuing portion 64e1 is bent in the direction opposite to the predetermined direction from the split part 64a1 that is disposed at the bottom end of the vertical portion 64a on the side where the circuit pattern 42 is disposed. The parallel portion 64e2 continues from the continuing portion 64e1 and extends in parallel to the circuit pattern 42, and a circuit pattern bonding region 64e3 provided on the rear surface of the parallel portion 64e2 is bonded to the circuit pattern 42.

Connected to the body portion 61 via the interlinking portion 63, the above leg portion 64 is attached to the circuit pattern 42 in such a manner that the predetermined direction with respect to the divided portions 64b to 64e is parallel to the wiring direction of the body portion 61. In the leg portion 64, the length from the split part 64a1 to an end of the divided portion 64b in the predetermined direction, the length from the split part 64a1 to an end of the divided portion 64c in the direction opposite to the predetermined direction, the length from the split part 64a1 to an end of the divided portion 64d in the predetermined direction, and the length from the split part 64a1 to an end of the divided portion 64e in the direction opposite to the predetermined direction are all equal. In addition, since the divided portions 64b to 64e are obtained by making three cuts at equal intervals in the width direction of the vertical portion 64a, the divided portions 64b to 64e are equal in width and are therefore equal in area, and especially the parallel portions 64b2 to 64e2 are equal in area.

As in the first embodiment, the above leg portion 64 may be bonded to the circuit pattern 42 using the pressing portions 71 of the ultrasonic tools 70. In this case, however, as many ultrasonic tools 70 as the number of divided portions 64b to 64e of the leg portion 64 are prepared, and the divided portions 64b to 64e are vibrated and pressed simultaneously toward the circuit pattern 42 by the ultrasonic tools 70, thereby achieving the bonding of the leg portion 64.

As in the first embodiment, the front surface side and back surface side of the vertical portion 64a of the leg portion of the second embodiment are supported firmly by the divided portions 64b and 64c (64b to 64e), respectively. Therefore, the leg portion 64 is bonded to the circuit pattern 42 stably. In addition, the divided portions 64b and 64c (64b to 64e) of the leg portion 64 are bonded to the circuit pattern 42 simultaneously by ultrasonic vibration. In doing so, the divided portions 64b and 64c (64b to 64e) are deformed in parallel to the bending directions in the same way, so that misalignment of the vertical portion 64a does not occur. Therefore, the lead frame 60 is maintained at the predetermined bonding position without the misalignment and the like of the vertical portion 64a. As a result, the semiconductor device is manufactured properly.

The disclosed technique makes it possible to manufacture a semiconductor device properly while preventing misalignment of leg portions of lead frames from their bonding positions on circuit patterns.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
an insulated circuit substrate including an insulating board, and a circuit pattern disposed on the insulating board and being electrically connected to the semiconductor chip; and
a wiring member having a leg portion at one end thereof and an external connection terminal at another end thereof, the leg portion being bonded to the circuit pattern, wherein
the leg portion includes a vertical portion, a first divided portion, and a second divided portion, the vertical portion extending in a vertical direction that is orthogonal to a plane of the circuit pattern, and having a split end that is provided at a side of the vertical portion at which the circuit pattern is disposed, the first divided portion extending from the split end in a first direction that is parallel to the plane of the circuit pattern and being bonded to the circuit pattern, the second divided portion extending from the split end in a second direction opposite the first direction and being bonded to the circuit pattern.

2. The semiconductor device according to claim 1, wherein the leg portion has a planar shape, and the first divided portion and the second divided portion extend opposite to each other in a width direction of the leg portion.

3. The semiconductor device according to claim 2, wherein a thickness of the first divided portion and a thickness of the second divided portion are each half a thickness of the vertical portion.

4. The semiconductor device according to claim 2, wherein a width of the first divided portion and a width of the second divided portion are each half a width of the vertical portion.

5. The semiconductor device according to claim 4, wherein the leg portion includes a plurality of pairs of leg portions, each of which includes the first divided portion and the second divided portion.

6. The semiconductor device according to claim 4, wherein in a plan view of the semiconductor device, the first divided portion and the second divided portion have a same area size.

7. The semiconductor device according to claim 1, wherein
the first divided portion has a first end at a side of the first divided portion opposite to a side where the split end is located in the first direction, and the second divided portion has a second end at a side of the second divided portion opposite to a side where the split end is located in the second direction, and
a length from the split end to the first end and a length from the split end to the second end are the same.

8. The semiconductor device according to claim 1, wherein the leg portion included in the wiring member is provided in plurality, and the wiring member further includes a body portion to which is connected a top end of the vertical portion opposite to the split end of the vertical portion of each of the plurality of leg portions.

9. The semiconductor device according to claim 8, wherein the body portion extends in a wiring direction, and each of the plurality of leg portions is arranged in the wiring direction.

10. The semiconductor device according to claim 9, wherein each of the plurality of leg portions is connected to the body portion in such a manner that the first direction and the wiring direction are the same direction.

11. The semiconductor device according to claim 10, wherein the first divided portion and the second divided portion included in each of the plurality of leg portions are aligned in the wiring direction with respect to the body portion.

12. The semiconductor device according to claim 9, further comprising a heat dissipation plate, wherein
the insulated circuit substrate is provided in plurality, the plurality of insulated circuit substrates being arranged along the wiring direction on the heat dissipation plate, and
the wiring member extends in the wiring direction so that the body portion passes over the plurality of insulated circuit substrates, and each of the plurality of leg portions is bonded to a respective one of the plurality of insulated circuit substrates.

13. The semiconductor device according to claim 1, wherein
the leg portion further includes
a first continuing portion that has a bent shape to connect the split end of the vertical portion and the first divided portion and that has an elasticity, and
a second continuing portion that has a bent shape to connect the split end of the vertical portion and the second divided portion and that has an elasticity,
the first divided portion continuing from the first continuing portion and extending in the first direction, and
the second divided portion continuing from the second continuing portion and extending in the second direction.

14. A method of manufacturing a semiconductor device, comprising:
preparing an insulated circuit substrate including an insulating board and a circuit pattern disposed on the insulating board, and a wiring member including a leg portion to be bonded to the circuit pattern at one end thereof and an external connection terminal at another end thereof, the leg portion including a vertical portion, a first divided portion, and a second divided portion, the vertical portion extending in a vertical direction with respect to the circuit pattern, and having a split end that is provided at a side of the vertical portion at which the circuit pattern is disposed, the first divided portion extending from the split end toward a first direction that is parallel to the circuit pattern, and being bonded to the circuit pattern, the second divided portion extending from the split end in a second direction that is opposite to the first direction, and being bonded to the circuit pattern; and
mounting the first divided portion and the second divided portion of the leg portion on the circuit pattern and bonding the first divided portion and the second divided portion simultaneously to the circuit pattern by ultrasonic bonding.

15. The method of manufacturing the semiconductor device according to claim 14, wherein
the leg portion included in the wiring member is provided in plurality, the insulated circuit substrate is provided in plurality, and each of the plurality of leg portions is bonded to a respective one of circuit patterns of the plurality of insulated circuit substrates.

16. The method of manufacturing the semiconductor device according to claim 14, wherein
the leg portion further includes
a first continuing portion that connects the split end of the vertical portion and the first divided portion and that has an elasticity, and
a second continuing portion that connects the split end of the vertical portion to the second divided portion and that has an elasticity,
the first divided portion, continuing from the first continuing portion to extend in a direction parallel to the plane of the circuit pattern, and
the second divided portion, continuing from the second continuing portion to extend in a direction parallel to the circuit pattern.

17. A method of manufacturing a semiconductor device, comprising:
preparing a plurality of insulated circuit substrates arranged in one direction, the plurality of insulating circuit substrates each including an insulating board and a circuit pattern disposed on the insulating board, and a wiring member including a plurality of leg portions at one end thereof and an external connection terminal at another end thereof, each of the plurality of leg portions to be bonded to the circuit pattern of a respective one of the plurality of insulating circuit substrates, the plurality of leg portions each including a vertical portion, a first divided portion, and a second divided portion, the vertical portion extending in a vertical direction orthogonal to a plane of the circuit pattern, and having a split end at a side of the vertical portion at which the circuit pattern is disposed, the first divided portion extending from the split end toward a first direction that is parallel to the plane of the circuit pattern, and being bonded to the circuit pattern, the second divided portion extending the split end in a second direction opposite to the first direction, and being bonded to the circuit pattern; and
mounting the first divided portion and the second divided portion of each of the plurality of leg portions on the circuit pattern, and along the one direction, for each of the plurality of leg portions, bonding the first divided portion and the second divided portion sequentially to the circuit pattern by ultrasonic bonding.
